(19) United States
(12) Patent Application Publication
(10) Pub. No.: US 2006/0121698 A1
(43) Pub. Date: Jun. 8, 2006

(54) Plastic film and heat-dissipating ring for chip cutting

(76) Inventor: Chih-Ming Hsu, Lujhu Township (TW)

Correspondence Address: PRO-TECHTOR INTERNATIONAL, 20775 Norada Court, Saratoga, CA, 95070-3018, US

(21) Appl. No.: 11/007,337

(22) Filed: Dec. 7, 2004

(51) Int. Cl. H01L 21/78; H01L 21/50

(52) U.S. Cl. 438/464; 438/463; 438/460; 438/113

(57) ABSTRACT

A transparent plastic film for chip cutting is made of polyethylene terephathalate that has an excellent transmittance to laser beams. When a laser beam passes through the plastic film and a chip mounted on a central area of an upper face of the plastic film, the heat generated during penetration of the laser beam through the plastic film is less than that in the conventional plastic films, avoiding damage to the plastic film and replacement of the plastic film. A heat-dissipating ring may be mounted on the upper face of the plastic film and located in a central hole of a supporting ring adhered to a perimeter of the upper face of the plastic film. The heat-dissipating ring surrounds the chip to cover a return point of the laser beam, preventing the plastic film from being damaged.

### BACKGROUND OF THE INVENTION

1. Field of the Invention

The present invention relates to a plastic film. In particular, the present invention relates to a plastic film for chip cutting by laser. The present invention also relates to a heat-dissipating ring for chip cutting by laser.

2. Description of the Related Art

In current procedures for manufacturing light-emitting diodes (LEDs) and memories, numerous densely arrayed crystallite units are produced on a chip, and a laser cutting apparatus is used to cut the crystalline units into numerous crystallites. Before the laser cutting procedure, the chip is adhered on a central area of an upper face of a see-through plastic film placed on a working table of the laser cutting apparatus, with a metal supporting ring adhered to a perimeter of the plastic film. An electronic microcamera is mounted above the working table for observing the arrangement and location of each crystallite unit in the epilayer (or epitaxy layer) of the chip. The chip is cut by a laser beam from top to obtain individual crystallites.

A typical plastic film is made of polyvinyl chloride (PVC) or polyethylene (PE), both of which have an unsatisfactory transmittance to laser beams. Thus, a considerable amount of heat is generated when a laser beam passes through the plastic film, causing damage to the plastic film. As a result, the plastic film has to be replaced with a new one after the chip cutting procedure, which is labersome and time-consuming. The ratio of qualified crystallites is reduced. The plastic film currently used in chip cutting has a color and thus has a poor transmittance to laser beams. As a result, the color plastic film breaks more easily.

Further, the plastic film receives excessive laser energy at a return point of each chip cutting travel. In other words, the plastic film breaks easily at the return point. Further, the plastic film could not provide a satisfactory heat-dissipating effect. The overheated crystallites are damaged accordingly.

### SUMMARY OF THE INVENTION

An objective of the present invention is to provide a plastic film that is a transparent film made of polyethylene terephathalate.

Another objective of the present invention is to provide a metal heat-dissipating ring for dissipating heat.

In accordance with an aspect of the invention, a plastic film for chip cutting is provided. In an embodiment of the invention, the plastic film is a transparent plastic film made of polyethylene terephathalate (PET) that has an excellent transmittance to laser beams. Preferably, the transparent film is colorless.

When a laser beam passes through the plastic film and a chip mounted on a central area of an upper face of the plastic film, the heat generated during penetration of the laser beam through the plastic film of PET is less than that in the case of conventional plastic films of PVC and PE. Damage to the plastic film is avoided. Replacement of the plastic film is not required accordingly.

In accordance with another aspect of the invention, a heat-dissipating ring is mounted on an upper face of a plastic film and located in a central hole of a supporting ring adhered to a perimeter of the upper face of the plastic film. The heat-dissipating ring is preferably made of metal. The heat-dissipating ring surrounds the chip to cover a return point of the laser beam, preventing the plastic film from being damaged.

In an embodiment of the invention, the heat-dissipating ring has an inner diameter the same as that of the chip. Further, the heat-dissipating ring assists in dissipating heat from the chip and the plastic film, preventing the crystallites from being damaged and thus improving the ratio of the qualified crystallites.

In an alternative embodiment, the heat-dissipating ring has an inner diameter greater than the diameter of the chip by not more than 20 mm. In another alternative embodiment, the heat-dissipating ring and has a minimum inner diameter smaller than the diameter of the chip by not more than 2 mm.

Other objectives, advantages, and novel features of the invention will become more apparent from the following detailed description when taken in conjunction with the accompanying drawings.

### BRIEF DESCRIPTION OF THE DRAWINGS

FIG. 1 is a perspective view of a chip, a supporting ring, and a plastic film in accordance with the present invention.

FIG. 2 is an exploded perspective view of the chip, the supporting ring, and the plastic film in FIG. 1.

FIG. 3 is a sectional view of the chip and a central portion of the plastic film in FIG. 1.

FIG. 4 is a perspective view of a chip, a supporting ring, a plastic film, and a heat-dissipating ring in accordance with the present invention.

FIG. 5 is a sectional view of the chip, a central portion of the plastic film, and the heat-dissipating ring in FIG. 4.

FIG. 6 is a sectional view similar to FIG. 5, illustrating a modified embodiment of the present invention.

FIG. 7 is a sectional view similar to FIG. 5, illustrating another modified embodiment of the present invention.

### DETAILED DESCRIPTION OF THE PREFERRED EMBODIMENTS

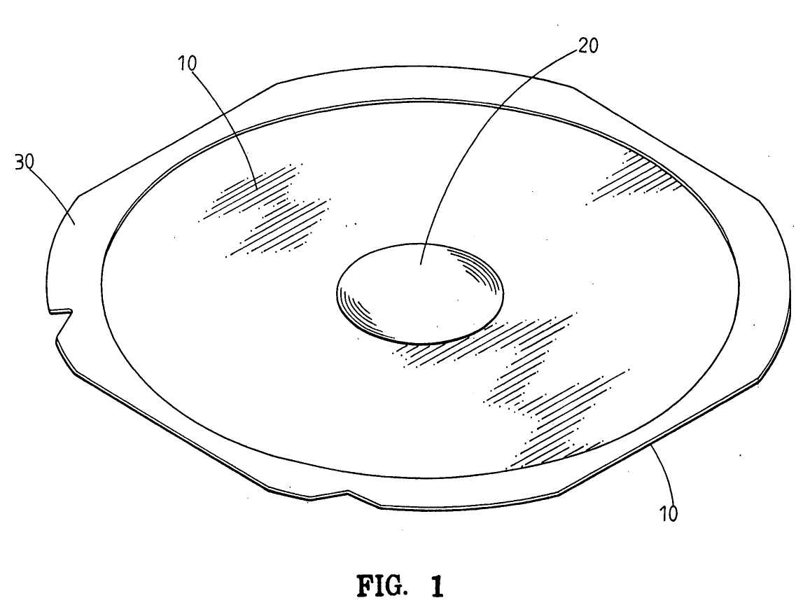

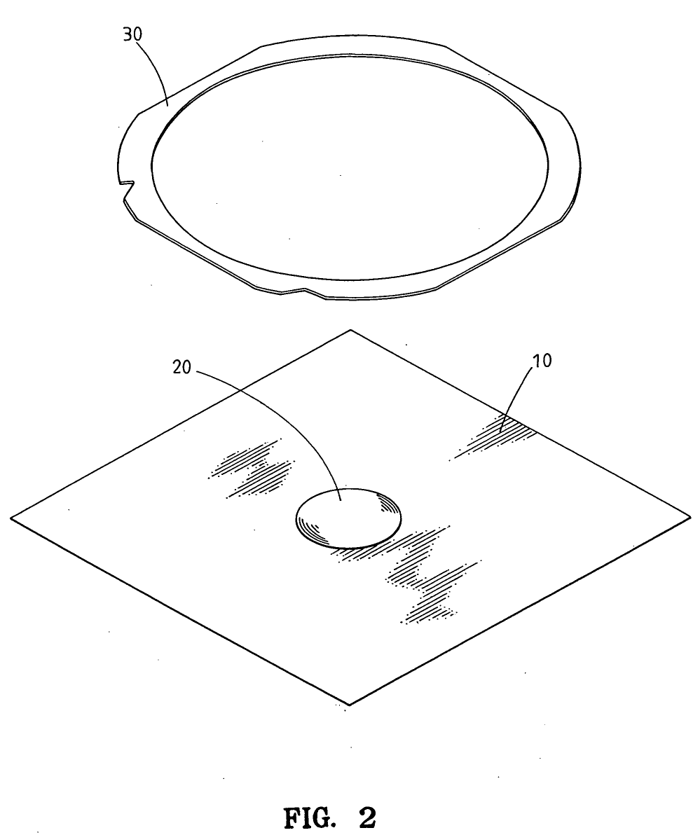

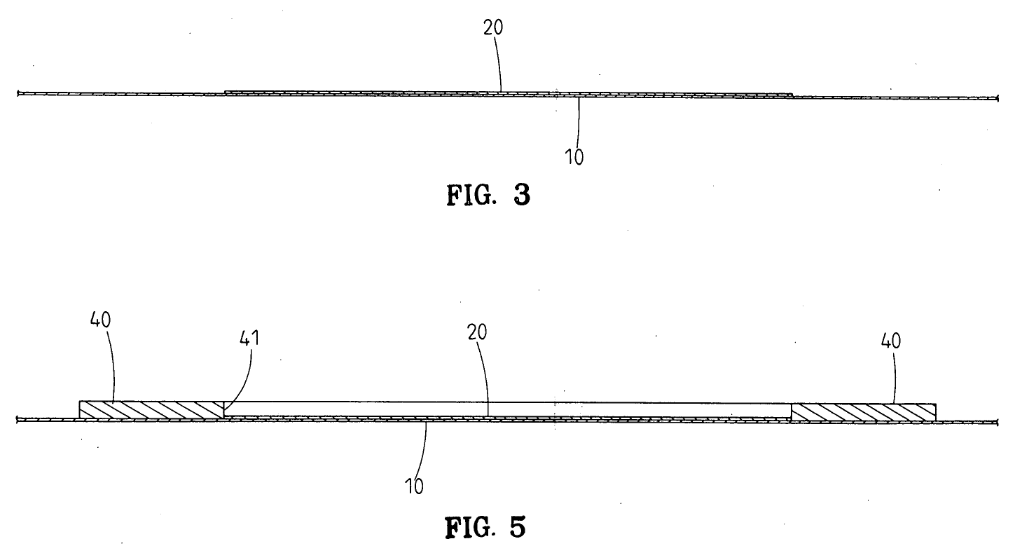

Referring to FIGS. 1 through 3, a plastic film for chip cutting in accordance with the present invention is a see-through plastic film 10. Preferably, the plastic film 10 is a transparent film made of polyethylene terephathalate (PET) that has an excellent transmittance to laser beams. Preferably, the transparent plastic film is colorless.

A circular chip 20 is adhered to a central area of an upper face of the plastic film 10, and a metal supporting ring 30 is adhered to a perimeter of the upper face of the plastic film 10. Thus, the chip 20 is located in a center of a central hole (not labeled) of the supporting ring 30.

When a laser beam passes through the chip 20 and the plastic film 10 from top, the heat generated during penetration of the laser beam through the plastic film 10 of PET is less than that in the case of conventional plastic films of PVC and PE. Damage to the plastic film 10 is avoided. Replacement of the plastic film 10 is not required accordingly.

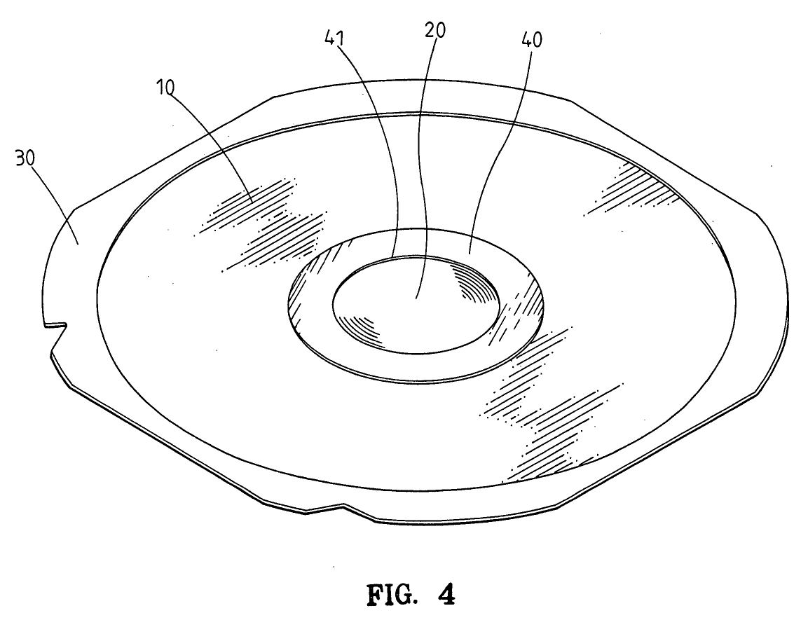

A heat-dissipating ring 40 can be added, as illustrated in FIGS. 4 and 5. In this embodiment, the heat-dissipating ring 40 is made of metal and mounted on the upper face of the plastic film 10 and located in the central hole of the supporting ring 30. The heat-dissipating ring 40 surrounds the chip 20 and has an inner diameter the same as a diameter of the chip 20. The return point of the laser beam is thus covered by the heat-dissipating ring 40. The laser beam that causes damage at the return point in the prior art plastic films hits the metal heat-dissipating ring 40, preventing the plastic film 10 from being damaged. Further, the heat-dissipating ring 40 assists in dissipating heat from the chip 20 and the plastic film 10, preventing the crystallites from being damaged and thus improving the ratio of the qualified crystallites.

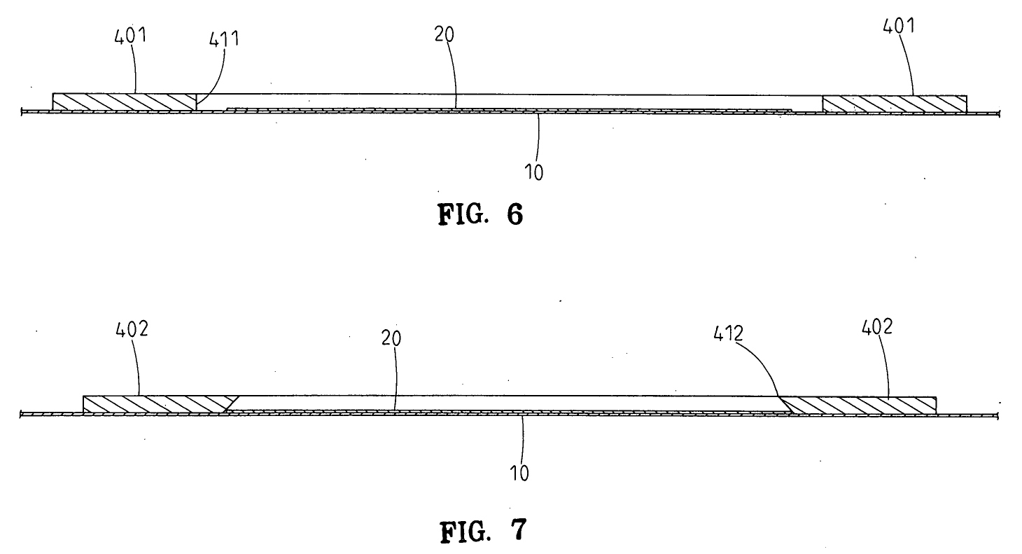

FIG. 6 illustrates a modified embodiment, wherein the heat-dissipating ring 40 has a hole 411 with an inner diameter greater than the diameter of the chip 20. Preferably, the inner diameter of the heat-dissipating member 40 is greater than the diameter of the chip 20 by not more than 20 mm.

FIG. 7 illustrates another modified embodiment, wherein the hole 412 of the heat-dissipating ring 40 is conic and has a minimum inner diameter smaller than the diameter of the chip 20. Preferably, the minimum inner diameter of the heat-dissipating ring 40 is smaller than the diameter of the chip 20 by not more than 2 mm.

Although specific embodiments have been illustrated and described, numerous modifications and variations are still possible without departing from the essence of the invention. The scope of the invention is limited by the accompanying claims.

What is claimed is:

1. A plastic film for chip cutting by laser, the plastic film being a transparent plastic film made of polyethylene terephathalate, a chip being adapted to be mounted on a central area of an upper face of the plastic film.

2. The plastic film for chip cutting by laser beams as claimed in claim 1 wherein the transparent plastic film is colorless.

3. A combination of a plastic film and a heat-dissipating ring for chip cutting by laser, comprising:
a transparent plastic film, a chip being adapted to be mounted on a central area of an upper face of the transparent plastic film; and
a heat-dissipating ring mounted on the upper face of the transparent plastic film, the heat-dissipating ring surrounding the chip and covering a return point of a laser beam for cutting the chip.

4. The combination as claimed in claim 3 wherein the transparent plastic film is colorless.

5. The combination as claimed in claim 3 wherein the heat-dissipating ring includes an inner diameter the same as a diameter of the chip.

6. The combination as claimed in claim 3 wherein the heat-dissipating ring includes an inner diameter greater than a diameter of the chip by not more than 20 mm.

7. The combination as claimed in claim 3 wherein the heat-dissipating ring includes a minimum diameter smaller than a diameter of the chip by not more than 2 mm.

8. The combination as claimed in claim 3 wherein the transparent plastic film is made of polyethylene terephathalate.

9. The combination as claimed in claim 8 wherein the heat-dissipating ring includes an inner diameter the same as a diameter of the chip.

10. The combination as claimed in claim 8 wherein the heat-dissipating ring includes an inner diameter greater than a diameter of the chip by not more than 20 mm.

11. The combination as claimed in claim 8 wherein the heat-dissipating ring includes a minimum diameter smaller than a diameter of the chip by not more than 2 mm.
